(19) United States
(12) Patent Application Publication
(10) Pub. No.: US 2014/0061864 A1
(43) Pub. Date: Mar. 6, 2014

(54) SEMICONDUCTOR SUBSTRATE HAVING CRACK PREVENTING STRUCTURE AND METHOD OF MANUFACTURING THE SAME

(71) Applicant: SAMSUNG ELECTRO-MECHANICS CO., LTD., Suwon (KR)

(72) Inventors: Jin Gul HYUN, Suwon (KR); Mi Jin Park, Suwon (KR); Kyung Seob Oh, Suwon (KR)

(73) Assignee: Samsung Electro-Mechanics Co., Ltd., Suwon (KR)

(21) Appl. No.: 13/827,810

(22) Filed: Mar. 14, 2013

(30) Foreign Application Priority Data
Sep. 4, 2012 (KR) 10-2012-0097685

(51) Int. Cl. H01L 23/00

(52) U.S. Cl. CPC H01L 23/562
USPC 257/620; 438/462

(57) ABSTRACT

Disclosed herein is a semiconductor substrate having a crack preventing structure, the semiconductor substrate including: a plurality of wiring layers and a plurality of insulating layers sequentially stacked on a device divided into integrated circuit device areas and a cutting area separating the device areas from each other; opening parts formed to spatially separate the insulating layers in the device areas and the insulating layers in the cutting area from each other; and chamfering parts formed at outer sides of the insulating layers in the device areas contacting the opening parts, wherein the plurality of wiring layers are formed between the insulating layers in the cutting area and the device.

### CROSS REFERENCE(S) TO RELATED APPLICATIONS

This application claims the benefit under 35 U.S.C. Section 119 of Korean Patent Application Serial No. 10-2012-0097685, entitled “Semiconductor Substrate Having Crack Preventing Structure and Method of Manufacturing the Same” filed on Sep. 4, 2012, which is hereby incorporated by reference in its entirety into this application.

### BACKGROUND OF THE INVENTION

1. Technical Field

The present invention relates to a semiconductor substrate having a crack preventing structure and a method of manufacturing the same, and more particularly, to a semiconductor substrate having a crack preventing structure capable of preventing generation of a crack at the time of cutting a semiconductor by forming insulating layers and wiring layers in an integrated circuit device area and a cutting area and forming opening parts so as to spatially separate the insulating layers in the device area and the insulating layers in the cutting area from each other, and a method of manufacturing the same.

2. Description of the Related Art

Currently, in accordance with the rapid progress of slimness and lightness of products in mobile communication and various electronic fields, the use of integrated circuit devices in which fine patterns having various and complicated forms are formed on a multi-layer printed wiring board (PWB) device has increased.

In the integrated circuit device as described above, the fine patterns may be formed by repeating a process of stacking an insulating layer capable of accomplishing inter-layer insulation on the PWM device and protecting circuits and a process of stacking a metal wiring on the insulating layer by plating.

A plurality of integrated circuit devices are simultaneously formed collectively on a semiconductor wafer and are divided into individual integrated circuit devices, that is, semiconductor chips through a cutting process called a routing process.

FIG. 1 is a cross-sectional view showing a process of cutting a semiconductor wafer according to the related art. Referring to FIG. 1, a plurality of integrated circuit device areas 11 are arranged in a semiconductor wafer 10, and a cutting area 13 for dividing the plurality of integrated circuit device areas 11 into individual integrated circuit devices is arranged between the integrated circuit device areas 11.

An interlayer dielectric 15 is formed on the wafer 10, and a circuit wiring layer (not shown) configuring the integrated circuit device is formed in the integrated circuit device area 11.

The wafer 10 is cut through a cutting blade 1 to thereby be divided into the individual integrated circuit devices, that is, the semiconductor chips.

A crack is generated in the interlayer dielectric 15 due to chipping generated in the cutting area 13 at the time of a cutting process. The crack of the interlayer dielectric 15 generated in the cutting area 13 is transferred to the integrated circuit device area 11 to cause a defect in the circuit wiring layer.

For example, in the case of a memory device, the crack has a direct effect on a peripheral circuit or cell array to cause a defect in the peripheral circuit or cell array, thereby deteriorating package test yield and product reliability.

### SUMMARY OF THE INVENTION

An object of the present invention is to provide a semiconductor substrate having a crack preventing structure capable of preventing generation of a crack at the time of cutting a semiconductor by forming insulating layers and wiring layers in an integrated circuit device area and a cutting area and forming opening parts so as to spatially separate the insulating layers in the device area and the insulating layers in the cutting area from each other, and a method of manufacturing the same.

According to an exemplary embodiment of the present invention, there is provided a semiconductor substrate having a crack preventing structure, the semiconductor substrate including: a plurality of wiring layers and a plurality of insulating layers sequentially stacked on a device divided into integrated circuit device areas and a cutting area separating the device areas from each other; opening parts formed to spatially separate the insulating layers in the device areas and the insulating layers in the cutting area from each other; and chamfering parts formed at outer sides of the insulating layers in the device areas contacting the opening parts, wherein the plurality of wiring layers are formed between the insulating layers in the cutting area and the device.

The opening parts may be formed at sides of the insulating layers in the device areas and sides of the insulating layers in the cutting area so as to have a minimum interval of 400 μm or less.

The opening parts may be formed in a closed loop form in which they enclose a circumference of the device area, when viewed in a plane.

According to another exemplary embodiment of the present invention, there is provided a method of manufacturing a semiconductor substrate having a crack preventing structure, the method including: a step (a) of stacking first wiring layers on a device divided into integrated circuit device areas and a cutting area separating the device areas from each other; a step (b) of stacking first insulating layers in the device areas except for the cutting area on the device as well as the first wiring layers; a step (c) of stacking second wiring layers in the device areas on the first insulating layers and in the cutting area; a step (d) of stacking second insulating layers in the device areas on the first insulating layers as well as the second wiring layers and stacking a third insulating layer in the cutting area so as to be spatially separated from the second insulating layers; a step (e) of stacking third wiring layers on the second insulating layers and stacking a fourth wiring layer on the third insulating layer so as to be spatially separated from the third wiring layers; a step (f) of stacking fourth insulating layers on the second insulating layer as well as the third wiring layer and stacking a fifth insulating layer on the third insulating layer as well as the fourth wiring layer so as to be spatially separated from the fourth insulating layers; and a step (g) of cutting the cutting area to separate the integrated circuit device areas from each other.

In the step (b), a first opening part including the cutting area may be formed between the first insulating layers, and first chamfering parts may be formed at outer sides of the first insulating layers contacting the first opening part.

In the step (d), a second opening part spatially separating the second insulating layers and the third insulating layer from each other may be formed, and second chamfering parts may be formed at outer sides of the second insulating layers contacting the second opening part. The second opening part may be formed to have an interval of 400 μm or less.

In the step (e), wiring layer cutting parts may be formed at a width corresponding to that of the second opening part between the third wiring layers and the fourth wiring layer.

In the step (f), the fifth insulating layer may be formed to be narrower than the cutting area.

### BRIEF DESCRIPTION OF THE DRAWINGS

FIG. 1 is a cross-sectional view describing a method of cutting a semiconductor wafer according to the related art;

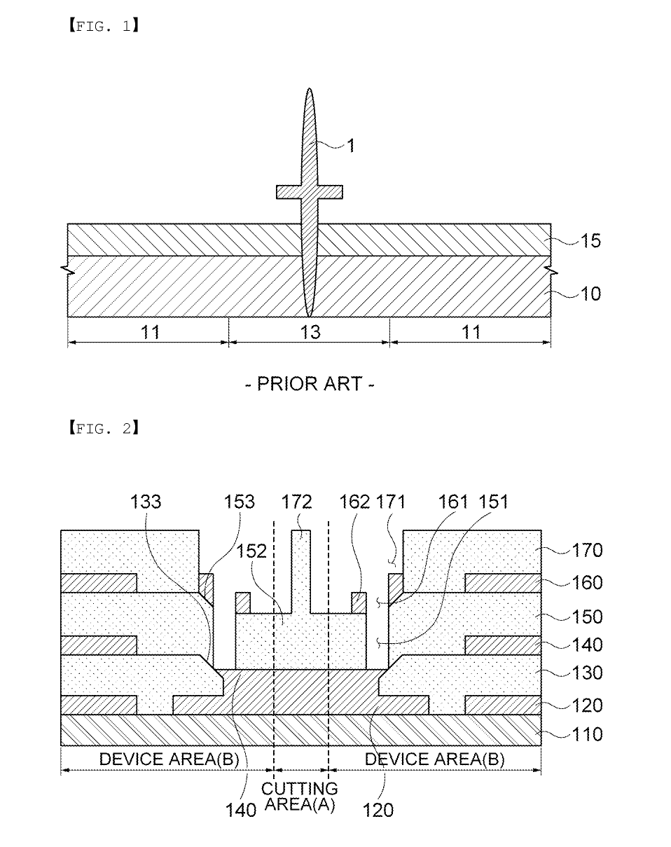

FIG. 2 is a conceptual diagram showing a semiconductor substrate having a crack preventing structure according to an exemplary embodiment of the present invention; and

FIGS. 3A to 3E are views sequentially showing a process of manufacturing a semiconductor substrate having a crack preventing structure according to the exemplary embodiment of the present invention.

### DESCRIPTION OF THE PREFERRED EMBODIMENTS

Hereinafter, exemplary embodiments of the present invention will be described in detail with reference to the accompanying drawings.

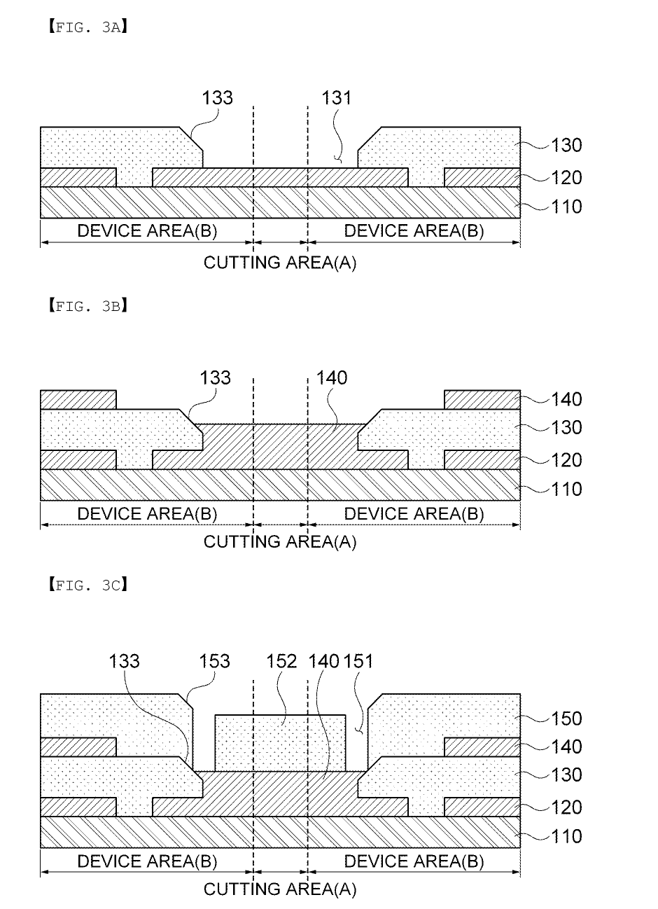

FIG. 2 is a conceptual diagram showing a semiconductor substrate having a crack preventing structure according to an exemplary embodiment of the present invention.

Referring to FIG. 2, the semiconductor substrate according to the exemplary embodiment of the present invention includes a plurality of wiring layers 120, 140, 160, and 162 and a plurality of insulating layers 130, 150, 152, 170, and 172 sequentially stacked on a device 110 divided into integrated circuit device areas B and a cutting area A separating the device areas B from each other.

Here, the device 110 is a concept including both of a form of a single layer substrate and a form of a circuit device having a multi-layer pattern.

The insulating layers 130, 150, and 170 in the device areas B and the insulating layers 152 and 172 in the cutting area A may be spatially separated from each other through opening parts 131, 151, and 171.

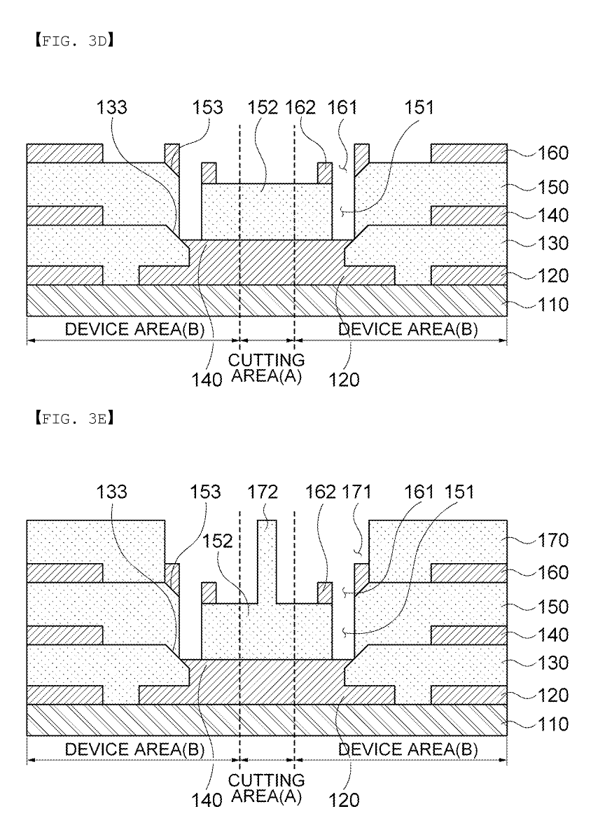

Here, referring to FIG. 3, the insulating layers 130, 150, and 170 in the device areas B is formed in a three-layer structure, and the insulating layers 152 and 172 in the cutting area A is formed in a two-layer structure.

In addition, the plurality of wiring layers 120 and 140 are formed between a third insulating layer 152 in the cutting area A and the device 110, that is, the opening part 131 of a first insulating layer 130, thereby making it possible to spatially separate the first insulating layers 130 in the device areas B and the third insulating layers 152 in the cutting areas A from each other.

Further, first and second chamfering parts 133 and 153 may be formed at outer sides of the insulating layers 130 and 150 in the device areas B contacting the opening parts 131, 151, and 171.

The first and second chamfering parts 133 and 153 as described above minimizes steps between the insulating layers in the cutting area A and the insulating layers in the device areas B, thereby making it possible to allow the insulating layers and the wiring layers to be stacked in various forms.

In addition, the opening parts 151 and 171 may be formed at sides of the insulating layers 130, 150, and 170 in the device areas B and sides of the insulating layers 152 and 172 in the cutting area A so as to have a minimum interval of 400 pm or less.

Further, the opening parts 151 and 171 may be formed in a closed loop form in which they enclose a circumference of the device area, when viewed in a plane.

Hereinafter, a method of manufacturing a semiconductor substrate having a crack preventing structure according to the exemplary embodiment of the present invention will be described.

FIGS. 3A to 3E are views sequentially showing a process of manufacturing a semiconductor substrate having a crack preventing structure according to the exemplary embodiment of the present invention.

First, as shown in FIG. 3A, after a step (a) of stacking first wiring layers 120 on a device 110 divided into integrated circuit device areas B and a cutting area A separating the device areas B from each other is performed, a step (b) of stacking first insulating layers 130 in the device areas B except for the cutting area A on the device 110 as well as the first wiring layers 120 is performed.

Here, in the step (b), a first opening part 131 including the cutting area A is formed between the first insulating layers 130, and first chamfering parts 133 are formed at outer sides of the first insulating layers 130 contacting the first opening part 131.

Then, as shown in FIG. 3B, a step (c) of stacking second wiring layers 140 in the device areas B on the first insulating layers 130 and in the cutting area A is performed.

Here, the second wiring layers 140 are formed on the first insulating layers 130 and the first wiring layers 120.

Next, as shown in FIG. 3C, a step (d) of stacking second insulating layers 150 in the device areas B on the first insulating layers 130 as well as the second wiring layers 140 and stacking a third insulating layer 152 in the cutting area A so as to be spatially separated from the second insulating layers 150 is performed.

Here, in the step (d), a second opening part 151 spatially separating the second insulating layers 150 and the third insulating layer 152 from each other is formed, and second chamfering parts 153 are formed at outer sides of the second insulating layers 150 contacting the second opening part 151. Here, the second opening part 151 may be formed to have an interval of 400 μm or less.

Then, as shown in FIG. 3D, a step (e) of stacking third wiring layers 160 on the second insulating layers 150 and stacking a fourth wiring layer 162 on the third insulating layer 152 so as to be spatially separated from the third wiring layers 160 is performed.

Here, in the step (e), wiring layer cutting parts 161 may be formed at a width corresponding to that of the second opening part 151 between the third wiring layers 160 and the fourth wiring layer 162.

Next, as shown in FIG. 3E, a step (f) of stacking fourth insulating layers 170 on the second insulating layer 150 as well as the third wiring layer 160 and stacking a fifth insulating layer 172 on the third insulating layer 152 as well as the fourth wiring layer 162 so as to be spatially separated from the fourth insulating layers 170 is performed.

Here, in the step (f), the fifth insulating layer 172 may be formed to be narrower than the cutting area A.

Next, a step (g) of cutting the cutting area A to separate the integrated circuit device areas B from each other is performed.

Here, the step of stacking the fourth wiring layer 162 and the fifth insulating layer 172 in the cutting area A may also be omitted. However, according to the exemplary embodiment of the present invention, the fourth wiring layer 162 and the fifth insulating layer 172 are stacked to serve to complement steps generated between the cutting area A and the device areas B.

In the case in which the steps between the cutting area A and the device areas B are not maintained at an appropriate level, but are significantly widened, a void trap problem that an air bag is formed between the substrate and the device or a non-insulating layer problem may be generated.

Therefore, as in the exemplary embodiment of the present invention, it is preferable that the fourth wiring layer 162 and the fifth insulating layer 172 serving to complement the steps generated between the cutting area A and the device areas B are stacked in the cutting area A.

Here, the wiring layer and the insulating layer stacked in order to complement the step may be formed in a column shape in which they have a width narrower than the cutting area A as shown in shapes of the fourth wiring layer 162 and the fifth insulating layer 172.

According to the exemplary embodiment of the present invention, the first and second opening parts 131 and 151 and the first and second wiring layers 120 and 140 block a crack due to cutting stress from being transferred to the device areas B, thereby making it possible to increase reliability of a product.

According to the exemplary embodiment of the present invention, in forming the plurality of insulating layers 130, 150, and 170, the first and second chamfering parts 133 and 153 may be formed at outermost sides of at least two insulating layers 130 and 150.

The first and second chamfering parts 133 and 153 as described above minimize the steps between the insulating layers in the cutting area A and the insulating layers in the device areas B, thereby making it possible to allow the insulating layers and the wiring layers to be stacked in various forms.

The structure of the insulating layers according to the exemplary embodiment of the present invention as described above may also be formed as a structure of a multi-layer of four or more layers. Particularly, in the case in which the device 110 according to the exemplary embodiment of the present invention is manufactured in a form of a circuit device area and a substrate in which a plurality of insulating layers are stacked, semiconductor substrates having various forms may be provided.

For example, the stacking steps of (a) to (g) may be performed on outermost layers of the circuit device and the substrate.

As set forth above, according to the exemplary embodiment of the present invention, the insulating layers and the wiring layers are formed in the integrated circuit device area and the cutting area, and the opening parts are formed so as to spatially separate the insulating layers in the device areas and the insulating layers in the cutting area from each other to prevent generation of a crack at the time of cutting a semiconductor, thereby making it possible to prevent a defect in a cut portion of the semiconductor substrate and improve package test yield and reliability of the device.

In addition, according to the exemplary embodiment of the present invention, the semiconductor substrate including the plurality of insulating layers and wiring layers in the cutting area and having complicated and various structures may be manufactured.

Although the exemplary embodiments of the present invention has been described with reference to the accompanying drawings, those skilled in the art will appreciate that various modifications and alterations may be made without departing from the spirit or essential feature of the present invention. For example, those skilled in the art may modify materials, sizes, and the like, of each component according to an application or combine or substitute exemplary embodiments to practice forms that are not disclosed in the exemplary embodiment of the present invention, which does not depart from the scope of the present invention. Therefore, since the exemplary embodiment of the present invention described above is only an example, it is not to be restrictively interpreted. In addition, these modified exemplary embodiments are to be included in the technical spirit of the present invention as disclosed in the following claims.

What is claimed is:

1. A semiconductor substrate having a crack preventing structure, the semiconductor substrate comprising:
a plurality of wiring layers and a plurality of insulating layers sequentially stacked on a device divided into integrated circuit device areas and a cutting area separating the device areas from each other;
opening parts formed to spatially separate the insulating layers in the device areas and the insulating layers in the cutting area from each other; and
chamfering parts formed at outer sides of the insulating layers in the device areas contacting the opening parts,
wherein the plurality of wiring layers are formed between the insulating layers in the cutting area and the device.

2. The semiconductor substrate according to claim 1, wherein the opening parts are formed at sides of the insulating layers in the device areas and sides of the insulating layers in the cutting area so as to have a minimum interval of 400 μm or less.

3. The semiconductor substrate according to claim 2, wherein the opening parts are formed in a closed loop form in which they enclose a circumference of the device area, when viewed in a plane.

4. The semiconductor substrate according to claim 1, further comprising a wiring layer and an insulating layer stacked in the cutting area in order to complement steps generated between the cutting area and the devices areas.

5. A method of manufacturing a semiconductor substrate having a crack preventing structure, the method comprising:
a step (a) of stacking first wiring layers on a device divided into integrated circuit device areas and a cutting area separating the device areas from each other;
a step (b) of stacking first insulating layers in the device areas except for the cutting area on the device as well as the first wiring layers;
a step (c) of stacking second wiring layers in the device areas on the first insulating layers and in the cutting area;
a step (d) of stacking second insulating layers in the device areas on the first insulating layers as well as the second wiring layers and stacking a third insulating layer in the cutting area so as to be spatially separated from the second insulating layers;
a step (e) of stacking third wiring layers on the second insulating layers and stacking a fourth wiring layer on the third insulating layer so as to be spatially separated from the third wiring layers;
a step (f) of stacking fourth insulating layers on the second insulating layer as well as the third wiring layer and stacking a fifth insulating layer on the third insulating layer as well as the fourth wiring layer so as to be spatially separated from the fourth insulating layers; and
a step (g) of cutting the cutting area to separate the integrated circuit device areas from each other.

6. The method according to claim 5, wherein in the step (b), a first opening part including the cutting area is formed between the first insulating layers, and first chamfering parts are formed at outer sides of the first insulating layers contacting the first opening part.

7. The method according to claim 5, wherein in the step (d), a second opening part spatially separating the second insulating layers and the third insulating layer from each other is formed, and second chamfering parts are formed at outer sides of the second insulating layers contacting the second opening part.

8. The method according to claim 7, wherein the second opening part is formed to have an interval of 400 μm or less.

9. The method according to claim 5, wherein in the step (e), wiring layer cutting parts are formed at a width corresponding to that of the second opening part between the third wiring layers and the fourth wiring layer.

10. The method according to claim 5, wherein in the step (f), the fifth insulating layer is formed to be narrower than the cutting area.

11. The method according to claim 5, wherein the device of the step (a) is a circuit device or a substrate in which a plurality of insulating layers are stacked, and the stacking steps of (a) to (g) are performed on outermost layers of the circuit device and the substrate.
